(19) United States
(12) Patent Application Publication
(10) Pub. No.: US 2026/0022458 A1
(43) Pub. Date: Jan. 22, 2026

(54) VAPORIZER, PROCESSING APPARATUS, PROCESSING METHOD AND METHOD OF MANUFACTURING SEMICONDUCTOR DEVICE

(71) Applicant: KOKUSAI ELECTRIC CORPORATION, Tokyo (JP)

(72) Inventor: Shoki TANAKA, Toyama-shi (JP)

(73) Assignee: KOKUSAI ELECTRIC CORPORATION, Tokyo (JP)

(21) Appl. No.: 19/341,876

(22) Filed: Sep. 26, 2025

Related U.S. Application Data
(63) Continuation of application No. PCT/JP2023/025016, filed on Jul. 5, 2023.

(51) Int. Cl. C23C 16/448; C23C 16/52

(52) U.S. Cl. CPC C23C 16/448; C23C 16/52

(57) ABSTRACT

A vaporizer includes a main body that stores a liquid material at room temperature, a plurality of temperature sensors provided on a side wall of the main body, and a collector formed to collect the material on a side wall side on which a temperature sensor disposed at a lower end among the plurality of temperature sensors is provided.

### CROSS-REFERENCE TO RELATED APPLICATION

This application is a Bypass Continuation Application of PCT International Application No. PCT/JP2023/025016, filed on Jul. 5, 2023, the entire contents of which are incorporated herein by reference.

### BACKGROUND

### Field

The present disclosure relates to a vaporizer, a processing apparatus, a processing method, and a method of manufacturing a semiconductor device.

### Description of the Related Art

A semiconductor manufacturing apparatus for manufacturing a semiconductor device is known as an example of a processing apparatus that processes an object to be processed. Along with recent miniaturization of devices and the like, various processing gases such as a gas obtained by vaporizing a liquid or a gas obtained by sublimating a solid are sometimes used as the processing gas for processing a substrate. Stable supply of these processing gases at a predetermined flow rate has been required, and for example, the processing gas may be stably supplied while switching a plurality of containers, and the remaining amount of the material may be measured using a liquid level sensor.

### SUMMARY

The present disclosure provides a technology for estimating a remaining amount of a material based on a temperature detected by a temperature sensor.

According to one embodiment of the present disclosure, there is provided a technology including:
a main body that stores a liquid material at room temperature;
a plurality of temperature sensors provided on a side wall of the main body; and
a collector formed to collect the material on a side wall side on which a temperature sensor disposed at a lower end among the plurality of temperature sensors is provided.

### BRIEF DESCRIPTION OF THE DRAWINGS

FIG. 1 is a schematic configuration view of a processing apparatus suitably used in one embodiment of the present disclosure.

FIG. 2 is a cross-sectional view taken along line A-A of FIG. 1.

FIG. 3 is an explanatory diagram for describing a configuration of a vaporization system suitably used in one embodiment of the present disclosure.

FIG. 4 is a longitudinal cross-sectional view of a storage tank suitably used in one embodiment of the present disclosure.

FIG. 5 is a schematic configuration diagram of a controller 41 of the processing apparatus suitably used in one embodiment of the present disclosure, illustrating a control system of the controller 41 in a block diagram.

FIG. 6 is a diagram illustrating a display unit that displays transition of temperatures measured by a plurality of temperature sensors in one embodiment of the present disclosure.

FIG. 7 is a transverse cross-sectional view of a storage tank in one embodiment of the present disclosure.

FIG. 8 is a longitudinal cross-sectional view of a storage tank in Modified Example 1 of the present disclosure.

FIG. 9 is a longitudinal cross-sectional view of a storage tank in Modified Example 2 of the present disclosure.

FIG. 10A is a longitudinal cross-sectional view of a storage tank in Modified Example 3 of the present disclosure. FIG. 10B is a transverse cross-sectional view of the storage tank in Modified Example 3 of the present disclosure.

FIG. 11 is a longitudinal cross-sectional view of a storage tank in Modified Example 4 of the present disclosure.

FIG. 12A is a longitudinal cross-sectional view of a storage tank in Modified Example 5 of the present disclosure. FIG. 12B is a transverse cross-sectional view of the storage tank in Modified Example 5 of the present disclosure.

### DETAILED DESCRIPTION

### Embodiment of Present Disclosure

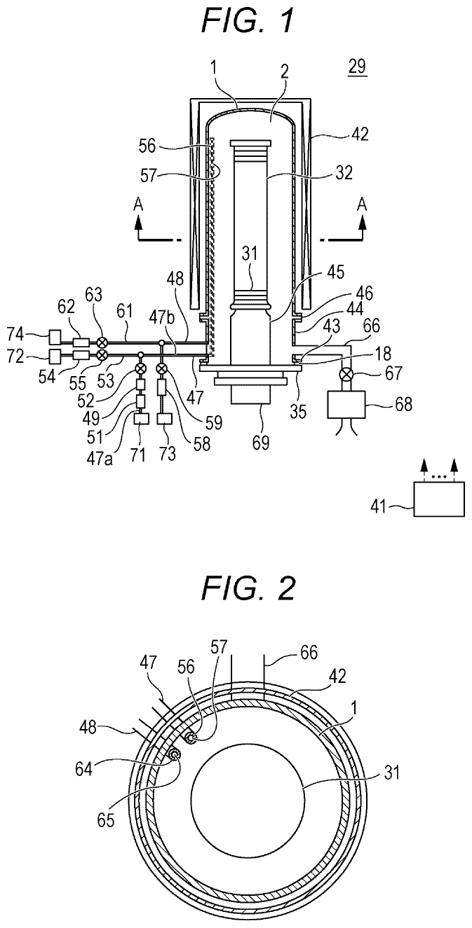

An embodiment of the present disclosure will be described below mainly with reference to FIGS. 1 to 7. The drawings used in the following description are all schematic, and dimensional relationships of respective elements, ratios of respective elements, and the like illustrated in the drawings do not necessarily coincide with actual ones. In addition, dimensional relationships of the respective elements, ratios of the respective elements, and the like do not necessarily coincide among the plurality of drawings.

### (1) CONFIGURATION OF PROCESSING APPARATUS

A reaction tube 1 is provided inside a heater 42 serving as a heating device, a manifold 44 constituted of, for example, stainless steel or the like is connected to a lower end of the reaction tube 1 via an O-ring 46 serving as an airtight member, a lower end opening (furnace opening) of the manifold 44 is airtightly closed by a seal cap 35 serving as a lid body via the O-ring 18 serving as an airtight member, and a process chamber 2 serving as a processing space is defined by at least the reaction tube 1, the manifold 44, and the seal cap 35.

A boat 32 serving as a holder is erected on the seal cap 35 via a boat support base 45, and the boat support base 45 serves as a holding body that holds the boat 32.

Two gas supply pipes (a gas supply pipe 47 and a gas supply pipe 48) serving as supply paths for supplying a plurality of types, here, two types of process gases, are provided to the process chamber 2.

The gas supply pipe 47 is provided with, in order from the upstream, a liquid material unit 71 serving as a liquid supplier, a storage unit 51, a mass flow controller (hereinafter referred to as MFC) 49 serving as a liquid flow rate control device (flow rate control means), and a valve 52 serving as an on-off valve. A purge gas supply pipe 53 for supplying an inert gas as a purge gas is joined to the downstream side of the valve 52. The purge gas supply pipe 53 is provided with a purge gas source 72, an MFC 54 serving as a flow rate control device (flow rate control means), and a valve 55 serving as an on-off valve in this order from the upstream.

In addition, a nozzle 56 is provided at a distal end portion of the gas supply pipe 47 from a lower portion to an upper portion along the inner wall of the reaction tube 1, and gas supply holes 57 for supplying gas are provided on a side surface of the nozzle 56. The gas supply holes 57 are provided at equal pitches from the lower portion to the upper portion, and have the same opening area.

Here, the vaporizer 60 of the present embodiment includes the MFC 49, the storage unit 51 including a storage tank (storage container) 200 that stores a liquid material as described later, and a heater 215 that heats the liquid material. In the description of the present embodiment, in the gas supply pipe 47, a pipe provided upstream of the storage tank 200 and between the storage tank 200 and the liquid material unit 71 is referred to as a supply pipe 47a. In the gas supply pipe 47, the downstream side of the storage tank 200 is defined as a supply pipe 47b.

The gas supply pipe 47, the MFC 49, the storage unit 51, the valve 52, and the nozzle 56 are collectively referred to as a first gas supplier (first gas supply line). The purge gas supply pipe 53, the MFC 54, and the valve 55 may be included in the first gas supplier. Further, the liquid material unit 71 and the purge gas source 72 may be included in the first gas supplier. The first gas supply line will be described later.

The gas supply pipe 48 is provided with a reactant gas source 73, an MFC 58 serving as a flow rate control device (flow rate control means), and a valve 59 serving as an on-off valve in order from the upstream direction, and a purge gas supply pipe 61 for supplying a purge gas to the downstream side of the valve 59 is joined. The purge gas supply pipe 61 is provided with a purge gas source 74, an MFC 62 serving as a flow rate control device (flow rate control means), and a valve 63 serving as an on-off valve in this order from the upstream. A nozzle 64 is provided at a distal end portion of the gas supply pipe 48 in parallel with the nozzle 56, and gas supply holes 65 serving as supply holes for supplying gas are provided on a side surface of the nozzle 64. The gas supply holes 65 are provided at equal pitches from the lower portion to the upper portion, and have the same opening area.

Here, the gas supply pipe 48, the MFC 58, the valve 59, and the nozzle 64 are collectively referred to as a second gas supply line serving as a second gas supplier. The purge gas supply pipe 61, the MFC 62, and the valve 63 may be included in the second gas supplier. Furthermore, the reactant gas source 73 and the purge gas source 74 may be included in the second gas supplier.

The liquid material supplied from the liquid material unit 71 joins the purge gas supply pipe 53 via the MFC 49, the storage unit 51, and the valve 52, and is further supplied to the process chamber 2 via the nozzle 56. When the material is supplied to the process chamber 2, the material vaporized in the vaporizer 60 is supplied. A reactant gas supplied from the reactant gas source 73 joins the purge gas supply pipe 61 via the MFC 58 and the valve 59, and is further supplied to the process chamber 2 via the nozzle 64.

The process chamber 2 is connected to a vacuum pump 68, which is an exhaust device (exhaust means), via a gas exhaust pipe 66 for exhausting gas, and is vacuum-exhausted. The valve 67 serving as an adjustment valve is configured to open and close the valve to enable vacuum-exhaustion and stop vacuum-exhaustion of the process chamber 2, and the valve 67 is configured to adjust the pressure of the process chamber 2 by further adjusting the opening degree of the valve.

The seal cap 35 is provided with a boat rotation mechanism 69, and the boat rotation mechanism 69 rotates the boat 32 in order to improve uniformity of processing.

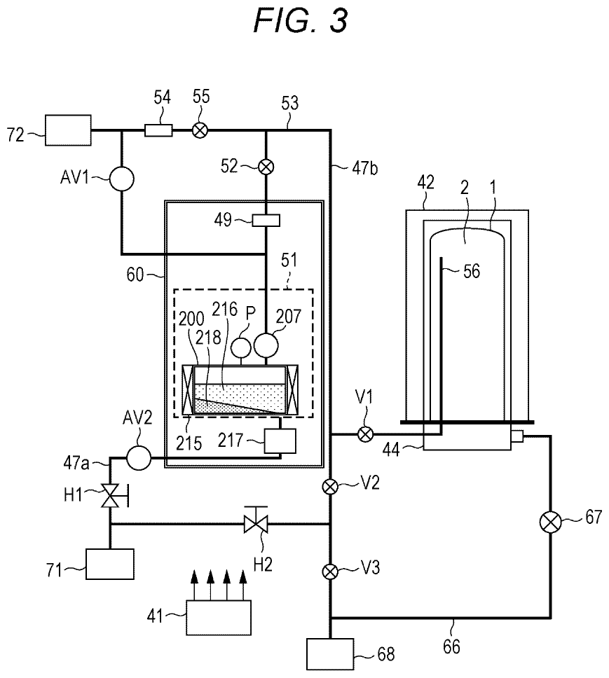

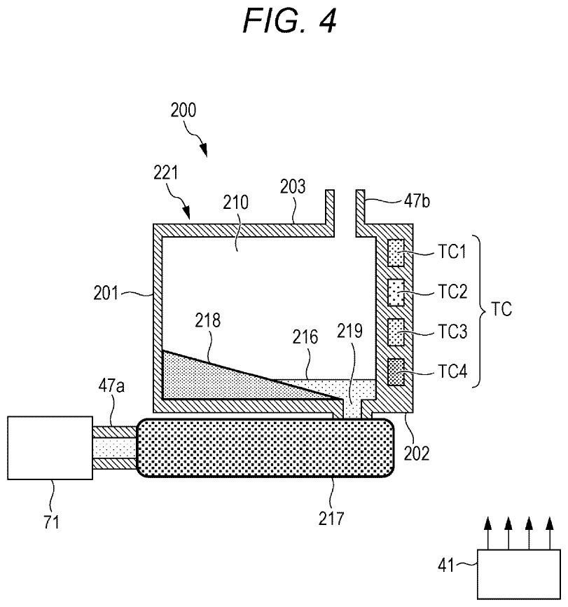

Next, a first gas supply line having a vaporizer 60 as a vaporization system will be described with reference to FIGS. 3 and 4. In FIG. 3, a wafer 31 in the process chamber 2 is omitted. In addition, the same components as those in FIG. 1 are denoted by the same reference numerals, and description thereof may be omitted.

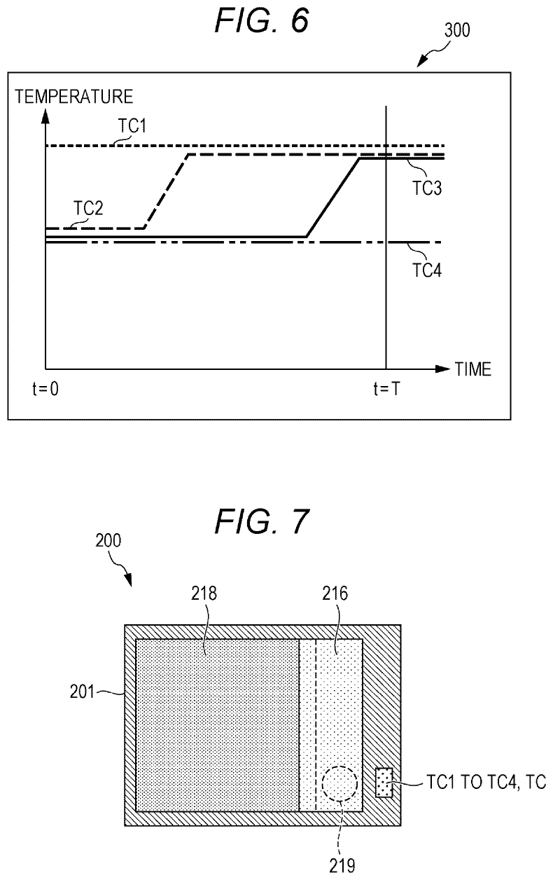

The vaporizer 60 includes a storage tank 200 serving as a storage container that stores a liquid material (liquid material) therein, an air valve 207, a pressure sensor P that detects the pressure in the storage tank 200, a heater 215 provided outside the side wall 201, a collector 218 formed to collect a liquid material 216 on the side of the side wall 201 provided with a temperature sensor TC4 disposed at a lower end in a vertical direction among the plurality of temperature sensors TC (generic name of temperature sensors TC1, TC2, TC3, and TC4) even when the remaining amount of the liquid material 216 in the storage tank 200 decreases, a storage unit 51 provided on the bottom wall 202 and including an opening 219 serving as a supply port for supplying the liquid material, a heater 217 serving as a preheater provided outside the bottom wall 202, and an MFC 49. The vaporizer 60 further includes a display unit 300 (see FIG. 6). Details of the display unit 300 will be described later. In the present specification, the liquid material stored in the storage tank 200 is referred to as the liquid material 216.

The liquid material 216 is heated and vaporized by the heater 215. The vaporized material joins the purge gas supply pipe 53 via the air valve 207, the MFC 49, the vaporizer 60, and the valve 52, and is further supplied to the process chamber 2 via a valve V1 and the nozzle 56. The storage tank 200 is configured to be able to estimate the remaining amount of the liquid material 216 based on the temperatures detected by the plurality of temperature sensors TC1 to TC4 provided on the side wall 201. When the remaining amount of the liquid material 216 decreases, the liquid material is supplied from the liquid material unit 71 into the storage tank 200 via the supply pipe 47a and the opening 219.

The amount of vaporized gas generated by vaporizing the liquid material 216 in the storage tank 200 varies depending on the remaining amount of the liquid material 216. For example, when the remaining amount of the liquid material 216 decreases, the heat transfer area from the heater 215 decreases, and the amount of generated vaporized gas also decreases. In this case, since the MFC 49 cannot adjust the flow rate to a flow rate exceeding the amount of generated vaporized gas, it is difficult to supply a predetermined amount of vaporized gas into the process chamber 2. On the other hand, in the vaporizer 60 in the present embodiment, the remaining amount of the liquid material 216 can be estimated by using the temperature change detected by the temperature sensors TC1 to TC4, and thus it is possible to replenish the liquid material when the amount of the liquid material 216 decreases to some extent. The estimation of the remaining amount of the liquid material 216 will be described later.

The collector 218 has a structure in which the liquid material 216 flows toward the opening 219 provided between the bottom wall 202 of the storage tank 200 and the supply pipe 47a when the remaining amount of the liquid material 216 decreases. With this structure, when the liquid material is introduced (replenished) into the storage tank 200 from the opening 219, it is possible to make the liquid material less susceptible to the influence of heating by the heater 215. Thus, it is possible to prevent the liquid material from being vaporized before being introduced into the storage tank 200. Therefore, a liquid material having a predetermined flow rate can be introduced (replenished) from the liquid material unit 71 into the storage tank 200.

The heater 215 is provided so as to surround or cover the side wall 201, and is configured to be able to heat the liquid material 216. The vaporized material causes, when re-liquefied, defects such as generation of particles. To prevent this, the heating temperature of the heater 215 is set to a temperature slightly higher than the vaporization temperature of the liquid material 216. Accordingly, it is possible to enhance the effect of preventing the reliquefaction of the liquid material 216 introduced into the storage tank 200.

On the other hand, the heater 217 is provided so as to cover the outer periphery of the supply pipe 47a, and is configured to heat the liquid material introduced into the storage tank 200. In order to supply the liquid material into the storage tank 200 in a liquid state, the heating temperature of the heater 217 is set to a temperature slightly lower than the vaporization temperature of the liquid material. Thus, it is possible to bring the liquid material closer to the vaporization temperature while replenishing the liquid material in the liquid state into the storage tank 200, so that the vaporization efficiency of the liquid material 216 can be improved.

The pressure sensor P is used to confirm vacuuming at the time of removing a remaining liquid material in the supply pipe 47 to be described later or the like, or to confirm vaporization behavior at the time of troubleshooting.

Here, when the air valve 207 is closed, the vaporized material remains between the air valve 207 and the valve 52. The remaining material stops flowing and re-liquefies. In order to prevent this reliquefaction, an air valve AV1 is opened, and an inert gas for purging the pipe between the air valve 207 and the MFC 49 and the inside of the MFC 49 is caused to flow to purge the remaining material (material gas). For example, by heating the purge gas to a temperature equal to or higher than the vaporization temperature by a heater (not illustrated), the effect of preventing the reliquefaction of the material gas can be enhanced. Whether the purge is performed can be confirmed by a detection value of the pressure sensor P.

By opening and closing an air valve AV2, the storage unit 51 is communicated from the liquid material unit 71 through the supply pipe 47a, and the material is supplied. By opening and closing the air valve 207, the process chamber 2 and the storage unit 51 communicate with each other through the supply pipe 47b, and the vaporized material is supplied. The vaporized material in the supply pipe 47b is supplied to the process chamber 2 when the air valve V1 is opened and air valves V2 and V3 are closed, and is supplied to the gas exhaust pipe 66 when the air valve V1 is closed and the air valves V2 and V3 are opened.

When the vaporized material remains as a residue in the supply pipe 47b and adheres to and accumulates on the inner wall of the supply pipe 47b, particles are formed. In the present embodiment, the material vaporized by the vacuum pump 68 is exhausted from the supply pipe 47b so that the vaporized material does not remain as a residue.

For example, after completion of the film forming step of the process recipe or after completion of the process recipe, the valve 52, the valve 55, and the air valve V1 are closed, and the air valves V2 and V3 are opened, and the vaporized material in the supply pipe 47b is exhausted by the vacuum pump 68. In addition, while the valve 55 is opened to supply the purge gas (for example, an inert gas) from the purge gas source 72, the air valve V1 may be closed and the air valves V2 and V3 may be opened to exhaust the vaporized material in the supply pipe 47b by the vacuum pump 68.

Hand valves H1 and H2 are provided to facilitate replacement of the liquid material unit 71. First, the hand valve H1 and the air valve V2 are closed, the hand valve H2 and the air valve V3 are opened, and the material in the pipe is removed by the vacuum pump 68. When the material in the pipe is removed, the hand valve H2 is closed, and the liquid material unit 71 is separated from the first gas supply line illustrated in FIG. 3 to replace the liquid material unit 71.

Similarly to FIG. 1, FIG. 3 illustrates a controller 41 serving as a control portion. The controller 41 is configured to be able to determine the remaining amount of the liquid material 216 according to a change in temperature measured by the temperature sensor TC.

For example, the controller 41 is configured to be able to determine the remaining amount of the liquid material 216 according to a change in temperature measured by the temperature sensor TC. When it is determined that the remaining amount of the liquid material 216 is large as a result of the remaining amount determination, the controller 41 causes the temperature sensor TC to continuously measure the temperature. Further, when it is determined that the remaining amount of the liquid material 216 is small, the controller 41 can manage the liquid material by issuing an alarm or the like to notify that the remaining amount is small or causing the storage tank 200 to be replenished with the liquid material from the liquid material unit 71. Details of the remaining amount determination of the liquid material 216 by the temperature sensor TC will be described later.

### (Storage Tank)

Next, the storage tank 200, which is a main part of the storage unit 51, which is a part of the vaporizer 60, will be described with reference to FIG. 4. FIG. 4 is a longitudinal cross-sectional view of the storage tank 200. Here, the heater 215 and the pressure sensor P are omitted. In the present specification, the longitudinal cross-sectional view of the storage tank 200 is a cross-sectional view of the storage tank 200 taken along the vertical direction, and the transverse cross-sectional view of the storage tank 200 is a cross-sectional view of the storage tank 200 taken along the horizontal direction. In the present specification, the upper side means a vertically upper side, and the lower side means a vertically lower side. In the present specification, a high position means a vertically upper position, and a low position means a vertically lower position.

The storage tank 200 is used as a container for storing a liquid material. The storage tank 200 includes a main body portion (container portion) 221 serving as a main body constituting a storage chamber 210 in which a liquid material is stored, a plurality of temperature sensors TC provided on a side wall 201, a collector 218 formed so as to collect the liquid material 216 on a side of the side wall 201 on which a temperature sensor TC4 disposed at a lower end (lowermost side) of the plurality of temperature sensors TC is provided, an opening 219 provided on a bottom wall 202 for supplying the liquid material, and a lid portion 203 provided with a flow path (supply pipe 47b) for discharging the material vaporized in the storage chamber 210. The side wall 201, the bottom wall 202, and the lid wall 203 constitute a main body portion 221 including an inner wall of the storage chamber 210.

With this configuration, the remaining amount of the liquid material 216 can be estimated based on the temperature detected (measured) by the temperature sensor TC. In particular, even when the amount of the liquid material 216 decreases, the temperature of the liquid material 216 can be detected by the temperature sensor TC4, and the remaining amount of the liquid material 216 can be estimated.

As illustrated in FIG. 4, in the side wall 201, a plurality of temperature sensors TC is arranged in a line in a height direction (vertical direction) of the side wall 201. Specifically, the temperature sensor TC1 is disposed on the uppermost side (upper end) of the side wall 201 in the vertical direction, the temperature sensors TC2 and TC3 are disposed on the lower side thereof in this order, and the temperature sensor TC4 is disposed on the lowermost side (lower end) thereof. The plurality of temperature sensors TC is disposed so as to be equally divided in the height direction of the side wall 201.

As illustrated in FIG. 6, a graph indicating transition (temperature change) of the temperature measured by the temperature sensor TC is displayed on the display unit 300. The vertical axis of the graph represents temperature, and the horizontal axis of the graph represents elapsed time. The dotted line (circle) of the graph indicates the transition of the temperature measured by the temperature sensor TC1, and is indicated by red (solid line) on the display unit 300, for example. The dotted line (corner) of the graph indicates the transition of the temperature measured by the temperature sensor TC2, and is indicated by blue (solid line) on the display unit 300, for example. The solid line of the graph indicates the transition of the temperature measured by the temperature sensor TC3, and is indicated in black (solid line) on the display unit 300, for example. The long dashed line with alternating two dots of the graph indicates the transition of the temperature measured by the temperature sensor TC4, and is indicated by yellow (solid line) on the display unit 300, for example. In this manner, the display unit 300 can display the transitions (temperature changes) of the temperatures measured by the plurality of temperature sensors TC arranged at different positions in different colors.

When the state of the liquid material 216 changes from liquid to vaporized gas, the temperature measured by each of the temperature sensors TC1 to TC4 changes (rises). The remaining amount of the liquid material 216 can be estimated based on the temperature change. Specifically, at time (t)=0, among the temperatures measured by the temperature sensors TC1 to TC4, the temperature measured by the temperature sensor TC1 is higher than the temperatures measured by the other temperature sensors TC2 to TC4. Thus, it can be estimated that the surface (liquid level) position of the liquid material 216 is a position higher than the arrangement position of the temperature sensor TC2 and lower than the arrangement position of the temperature sensor TC1 or near the arrangement position of the temperature sensor TC1. At t=T, only the temperature measured by the temperature sensor TC4 among the temperatures measured by the temperature sensors TC1 to TC4 does not change (rise). Thus, it can be estimated that the surface (liquid level) position of the liquid material 216 is a position higher than the arrangement position of the temperature sensor TC4 and lower than the arrangement position of the temperature sensor TC3 or near the arrangement position of the temperature sensor TC3.

As illustrated in FIG. 4, the collector 218 has an inclined surface (surface) having a predetermined inclination angle with respect to a horizontal plane so that, when the remaining amount of the liquid material 216 decreases, the remaining liquid material 216 flows toward the opening 219 provided at a position close to the temperature sensor TC4. In the present embodiment, the uppermost side (uppermost end) of the surface of the collector 218 is configured to be arranged at a position above the arrangement position of the temperature sensor TC4.

In the present embodiment, as illustrated in FIG. 4, in the longitudinal cross-sectional view of the storage tank 200, the surface of the collector 218 (the wetted surface of the liquid material 216) is configured as indicated by one straight line, and the collector 218 is indicated by a triangle.

FIG. 7 is a transverse cross-sectional view of the storage tank 200. A position of a straight line indicated by a dotted line is a position on the lowermost side (lower end) of the surface (inclined surface) of the collector 218. A circle indicated by a dotted line is the opening 219. The cross-sectional shape of the opening 219 may be other than a circle, and may be, for example, an ellipse, a polygon, a star, a rhombus, or a trapezoid. In addition, the cross-sectional shape of the storage tank 200 may be other than a quadrangle, and may be, for example, a circle, an ellipse, a triangle, a polygon with five or more sides, a star, a rhombus, or a trapezoid.

As illustrated in FIG. 7, the temperature sensors TC are disposed near the opening 219. Thus, even if the remaining amount of the liquid material 216 decreases, the liquid material can be replenished in the remaining amount management by the temperature detection of the liquid material 216 in the temperature sensor TC, so that the liquid material can be effectively used. In addition, it is sufficient that the temperature sensor TC4 disposed on the lowermost side (lower end) among the plurality of temperature sensors TC is disposed near the opening 219, and as illustrated in FIG. 7, all of the plurality of temperature sensors TC do not need to be disposed at the same position in the cross-sectional view.

The vaporization system according to the present embodiment includes at least: a storage tank 200 including a main body portion 221 that stores a liquid material at room temperature, a plurality of temperature sensors TC provided on a side wall 201 of the main body portion 221, and a collector 218 formed to collect the liquid material 216 on a side wall 201 side where the temperature sensors TC4 are provided; and a controller 41 configured to be able to estimate a remaining amount of the liquid material 216 according to a change in temperature measured by the plurality of temperature sensors TC.

The controller 41 is configured to be able to refill the liquid material from the liquid material unit 71 via the opening 219 based on the estimation of the remaining amount of the liquid material 216 according to the change in temperature measured by the plurality of temperature sensors TC.

The controller 41 is configured to be able to check the remaining amount of the liquid material 216 according to a change in temperature measured by the temperature sensor TC4 and determine whether the liquid material 216 is insufficient or replenishment is needed. The controller 41 is configured to replenish the liquid material from the liquid material unit 71 via the supply pipe 47a and the opening 219 when the amount of the liquid material 216 becomes so low that it needs to be replenished.

The controller 41 is configured to stop the supply of the liquid material from the liquid material unit 71 when the temperature measured by the temperature sensor TC1 disposed on the uppermost side (upper end) among the plurality of temperature sensors TC becomes saturated. Here, “the temperature measured by the temperature sensor TC1 becomes saturated” means that the temperature measured by the temperature sensor TC1 becomes a temperature state when the liquid material is measured. That is, the controller 41 is configured to stop the supply of the liquid material from the liquid material unit 71 when the surface (liquid level) position of the liquid material 216 is near the arrangement position of the temperature sensor TC1.

The controller 41 is configured to be able to supply the liquid material from the opening 219 based on the temperature detected by the temperature sensor TC4 disposed near the opening 219 provided in the bottom wall 202 of the storage tank 200.

In the present embodiment, the remaining amount of the liquid material 216 is estimated based on the change in temperature detected by the temperature sensor TC4 disposed at the lower end among the plurality of temperature sensors TC, but the present disclosure is not limited to this embodiment. For example, when the temperature detected by the temperature sensor TC3 among the plurality of temperature sensors TC changes, that is, when the remaining amount of the liquid material 216 decreases to the height at which the temperature sensor TC4 is disposed, the liquid material 216 can be replenished.

### (Control Portion)

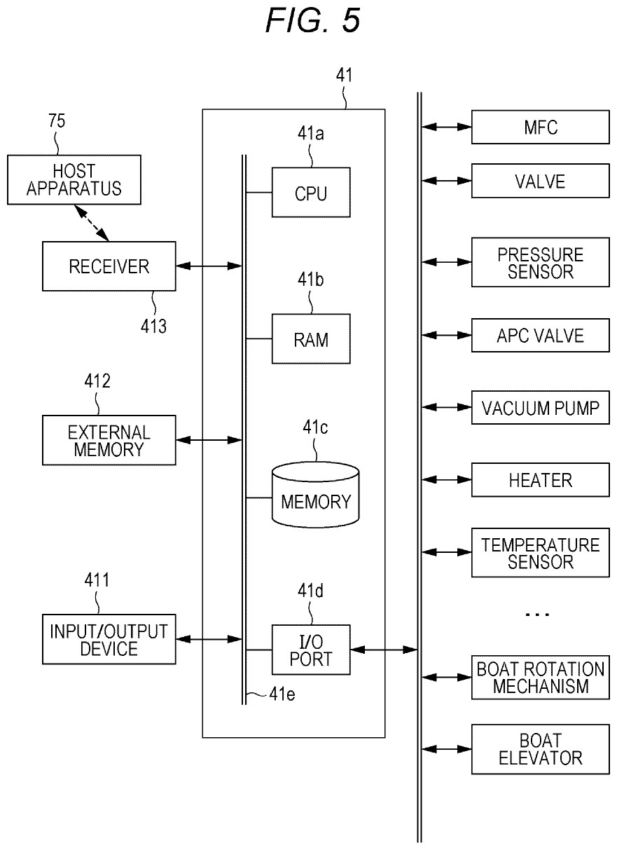

An outline of the controller 41 is illustrated in FIG. 5. The controller 41 serving as a control portion (control means) is configured as a computer including a central processing unit (CPU) 41a, a random access memory (RAM) 41b, a memory 41c, and an I/O port 41d. The RAM 41b, the memory 41c, and the I/O port 41d are configured to be able to exchange data with the CPU 41a via an internal bus 41e. An input/output device 411 configured as, for example, a touch panel or the like and an external memory 412 are configured to be connectable to the controller 41. Furthermore, a receiver 413 connected to a host apparatus 75 via a network is provided. The receiver 413 can receive information of another device from the host apparatus 75.

The memory 41c includes, for example, a flash memory, a hard disk drive (HDD), or the like. In the memory 41c, a control program that controls an operation of the processing apparatus, a process recipe in which procedures, conditions and the like of substrate processing to be described later are described and the like are readably recorded and stored. The process recipe functions as a program for causing the controller 41 to perform each procedure in the substrate processing step to be described later to obtain a predetermined result. Note that the term “program” in the present description may include only the process recipe alone, only the control program alone, or both of them. In addition, the RAM 41b is configured as a memory area (work area) in which a program, data, and the like read by the CPU 41a are temporarily stored.

The I/O port 41d is connected to the boat elevator, the heaters 42, 215, 217, the MFCs 49, 54, 58, and 62, the valves 52, 55, 59, 63, and 67, and the like.

The controller 41 performs flow rate adjustment of the MFCs 49, 54, 58, and 62, opening and closing operations of the valves 52, 55, 59, 63, and 67, temperature adjustment of the heaters 42, 215, and 217, start and stop of the vacuum pump 68, rotational speed adjustment of the boat rotation mechanism 69, lifting operation control of the boat elevator, and the like.

The controller 41 is not limited to being configured as a dedicated computer, and may be configured as a general-purpose computer. For example, the controller 41 according to the present embodiment can be configured by preparing the external memory (for example, a semiconductor memory such as a USB memory or a memory card, and the like) 412 storing the above-described program and installing the program in a general-purpose computer using the external memory 412. The means for supplying the program to the computer is not limited to the case of supplying the program via the external memory 412. For example, the program may be supplied using a communication means such as the Internet or a dedicated line instead of the external memory 412.

The memory 41c and the external memory 412 are configured as computer-readable recording media. Hereinafter, these are collectively referred to simply as a recording medium. In the present specification, the term “recording medium” may be used in a case including only the memory 41c alone, a case including only the external memory 412 alone, or a case including both.

### (2) PROCESSING METHOD

Next, an example of processing the wafer 31 serving as a substrate (object to be processed) will be described. Here, as an example of a process of manufacturing a semiconductor device, a cycle process of performing film processing by alternately supplying a source (material) and a reactant (reactant gas) to the process chamber 2 will be described.

In the film forming processing in the present embodiment, a film is formed on the wafers 31 by performing a predetermined number of times (one or more times) of a cycle of non-simultaneously performing a process (step 1) of supplying the material gas to the wafer 31 in the process chamber 2, a process (step 2) of removing the material gas (residual gas) from the process chamber 2, a process (step 3) of supplying the reactant gas to the wafer 31 in the process chamber 2, and a process (step 4) of removing the reactant gas (residual gas) from the process chamber 2.

### (Step 1)

In step 1, the material is caused to flow in a state where the heater 42 and the heater 215 are operated. First, the valve 52 and the valve 67 are opened. The material is supplied to the storage unit 51 via the supply pipe 47a. The material is stored in the storage chamber 210, and is heated and vaporized by the heater 215. The flow rate of the vaporized gaseous material (material gas) is adjusted by the MFC 49 and supplied to the supply pipe 47b. This material gas is supplied from the gas supply hole 57 of the nozzle 56 to the process chamber 2 and exhausted from the gas exhaust pipe 66. At this time, the material gas is supplied to the wafer 31 from the side of the wafer 31. Thus, a first layer is formed on the wafer 31.

### (Step 2)

Step 2 involves closing the valve 52 on the gas supply pipe 47 to stop supply of the material gas. The valve 67 of the gas exhaust pipe 66 is kept open, and a residual material gas is removed from the process chamber 2 by the vacuum pump 68. At this time, when an inert gas, for example, N₂ gas as a purge gas is supplied to the processing furnace 29, the effect of further eliminating the residual material gas is enhanced.

### (Step 3)

In step 3, the reactant gas valve 59 is opened to allow the reactant gas to flow into the gas supply pipe 48. The flow rate of the reactant gas is adjusted by the MFC 58, and the reactant gas is supplied from the gas supply hole 65 of the nozzle 64 to the process chamber 2 and exhausted from the gas exhaust pipe 66. At this time, the reactant gas is supplied to the wafer 31 from the side of the wafer 31. Thus, the first layer on the wafer 31 reacts with the reactant gas to be modified, and a second layer formed by modifying the first layer is formed on the wafer 31.

### (Step 4)

In step 4, after the second layer is formed, the valve 59 and the valve 63 are closed, the process chamber 2 is vacuum-exhausted by the vacuum pump 68, and the remaining reactant gas is removed. At this time, when an inert gas, for example, N₂ gas as a purge gas is supplied to the process chamber 2, the effect of further excluding the remaining reactant gas from the process chamber 2 is enhanced.

Steps 1 to 4 described above are defined as one cycle, and this cycle is repeated a plurality of times, whereby a film having a predetermined thickness can be formed on the wafer 31.

### (3) EFFECTS BY PRESENT EMBODIMENT

According to the present embodiment, one or a plurality of effects described below can be obtained.

(a) The remaining amount of the liquid material 216 can be estimated based on the transition (change in temperature) of the temperature measured by the plurality of temperature sensors TC provided on the side wall 201 of the main body portion 221.

The collector 218 is configured to collect the liquid material 216 on the side wall 201 side on which the temperature sensor TC4 disposed on the lowermost side (lower end) among the plurality of temperature sensors TC is provided, so that, even if the amount of the liquid material 216 decreases, for example, the temperature of the liquid material 216 can be detected by the temperature sensor TC4. Thus, since the remaining amount can be estimated even if the amount of the liquid material 216 decreases, the remaining amount of the liquid material 216 can be managed.

(b) The collector 218 has a structure in which, when the remaining amount of the liquid material 216 decreases, the remaining liquid material 216 flows toward the opening 219 provided at a position close to the temperature sensor TC4 disposed at the lowermost side (lower end) among the plurality of temperature sensors TC. Thus, even if the amount of the liquid material 216 decreases, for example, the temperature of the liquid material 216 can be detected by the temperature sensor TC4, and so that the liquid material can be replenished on the basis of the control of the remaining amount of the liquid material 216. Therefore, it is possible to effectively use the liquid material.

Further, since the opening 219 is provided in the bottom wall 202, it is possible to replenish the storage tank 200 with a preset flow rate of liquid material without being affected by the heater 215 provided outside the side wall 201.

(c) The uppermost end of the collector 218 is configured to be arranged at a position higher than the arrangement position of the temperature sensor TC4 arranged at the lower end among the plurality of temperature sensors TC. More specifically, the uppermost end (uppermost side) of the inclined surface (surface) of the collector 218 is disposed at a position above the arrangement position of the temperature sensor TC4. Thus, the inclination of the surface of the collector 218 (liquid contact surface of the liquid material 216) can be made steep. Therefore, even if the amount of the liquid material 216 decreases, the liquid material 216 can be easily collected on the temperature sensor TC4 side, so that the temperature of the liquid material 216 can be easily detected by the temperature sensor TC4, and the remaining amount of the liquid material 216 can be easily estimated. Thus, it is easy to manage the remaining amount of the liquid material 216.

(d) Since the plurality of temperature sensors TC is arranged so as to be equally divided in the height direction of the side wall 201, the temperature change detected by the plurality of temperature sensors TC occurs in a certain period of time, so that the remaining amount of the liquid material 216 can be easily estimated.

(e) In the longitudinal cross-sectional view of the storage tank 200, the surface of the collector 218 (liquid contact surface of the liquid material 216) is configured as indicated by one straight line. As described above, by providing the inclination in the collector 218, even if the amount of the liquid material 216 decreases, the liquid material 216 can be guided to the temperature sensor TC side, so that the temperature of the liquid material 216 can be detected by the temperature sensor TC, and the remaining amount of the liquid material 216 can be estimated. Thus, it is possible to manage the remaining amount of the liquid material 216.

(f) The controller 41 is configured to determine that the remaining amount of the liquid material 216 is insufficient when the temperature measured by the temperature sensor TC4 changes. Thus, it is possible to manage the remaining amount of the liquid material 216 according to a change in temperature detected by the temperature sensor TC4 disposed at the lowermost side (lower end) among the plurality of temperature sensors TC, for example, a temperature rise when the liquid material 216 is vaporized.

(g) The controller 41 is configured to cause the liquid material unit 71 to refill the liquid material from the opening 219. Specifically, the controller 41 is configured to be able to refill the liquid material from the liquid material unit 71 via the opening 219 based on the estimation of the remaining amount of the liquid material 216 according to the change in temperature measured by the plurality of temperature sensors TC. Thus, the remaining amount of the liquid material 216 can be reliably managed.

(h) The controller 41 is configured to stop the supply of the liquid material to the liquid material unit 71 when the temperature measured by the temperature sensor TC1 becomes saturated. Specifically, the controller 41 is configured to stop the supply of the liquid material from the liquid material unit 71 when the surface (liquid level) position of the liquid material 216 is near the arrangement position of the temperature sensor TC1 arranged on the uppermost side (upper end) among the plurality of temperature sensors TC. Thus, it is possible to maintain the liquid material 216 in the main body portion 221 within the predetermined amount, so that a space where the liquid material 216 is changed into the vaporized gas can be secured. When the liquid material is replenished into the storage tank 200, an appropriate amount (preset amount) of the liquid material can be replenished.

(i) The controller 41 is configured to be able to supply the liquid material from the opening 219 based on the temperature detected by the temperature sensor TC4 disposed near the opening 219 provided in the bottom wall 202 of the storage tank 200. Thus, it is possible to manage the remaining amount of the liquid material 216 according to a change in the temperature detected by the temperature sensor TC4, for example, a temperature rise when the liquid material 216 is vaporized. Furthermore, it is possible to supply the liquid material according to the remaining amount of the liquid material 216.

(j) The display unit 300 can easily grasp the remaining amount of the liquid material 216 by color-coding the temperature change to be measured according to the position where the plurality of temperature sensors TC is disposed.

(k) Since the heater 217 that heats the liquid material introduced into the main body portion 221 from the opening 219 is provided, the liquid material can be replenished in a state closer to the vaporization temperature, so that the vaporization efficiency of the liquid material 216 can be improved.

### (4) MODIFIED EXAMPLES

The storage tank 200 in the present aspect can be modified as in the following modified example. These modified examples can be arbitrarily combined. In the configuration of the storage tank described below, only elements different from those of the storage tank 200 illustrated in FIG. 4 will be described, and substantially the same elements are denoted by the same reference numerals, and the description thereof will be omitted. In the following modified example, the heater 217 is omitted. In addition, it is needless to say that the modified example can be appropriately used in combination with the above-described embodiment. The processing procedures and processing conditions at that time can be similar to the processing procedures and processing conditions in the above-described embodiment and modified examples, for example.

### Modified Example 1

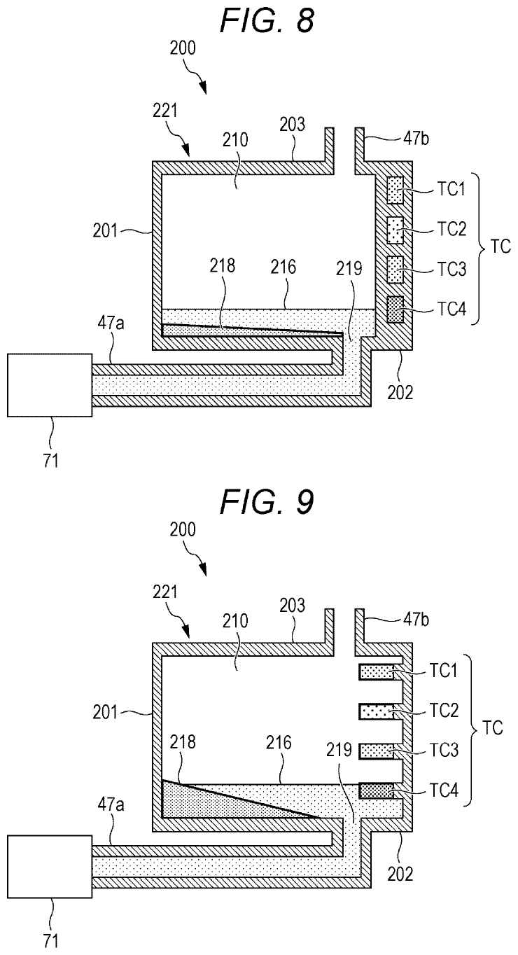

As illustrated in FIG. 8, the uppermost side (uppermost end) of the surface of the collector 218 may be disposed at a position lower than the arrangement position of the temperature sensor TC4 disposed at the lowermost side (lower end) among the plurality of temperature sensors TC. Also in the present modified example, effects can be obtained similar to those in the above-described embodiment. Further, in the present modified example, it is possible to employ an operation of replenishing the liquid material into the storage tank 200 at the timing when the temperature detected by the temperature sensor TC4 changes, that is, at the timing when the temperature detected by the temperature sensor TC4 reaches the vaporization temperature of the liquid material 216.

### Modified Example 2

As illustrated in FIG. 9, the side wall 201 may have a concavo-convex shape, and a plurality of temperature sensors TC may be installed in a protrusion protruding into the main body portion 221. Also in the present modified example, effects can be obtained similar to those in the above-described embodiment. Furthermore, according to the configuration of the present modified example, even if the remaining amount of the liquid material 216 decreases, for example, the temperature of the liquid material 216 can be easily detected by the temperature sensor TC4. Thus, it is easy to estimate the remaining amount of the liquid material 216, and it is also easy to manage the remaining amount of the liquid material 216.

### Modified Example 3

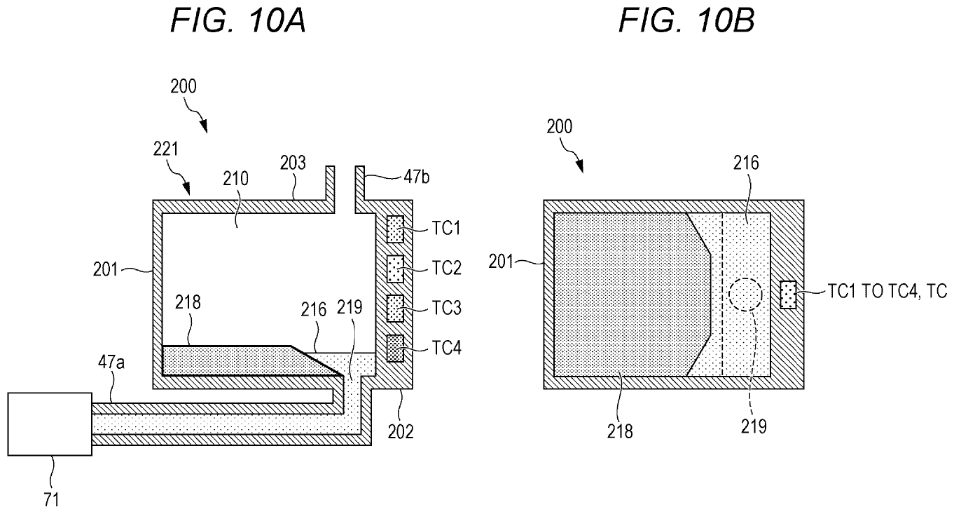

As illustrated in FIG. 10A, the surface of the collector 218 (the wetted surface of the liquid material 216) may be configured as indicated by a plurality of straight lines (for example, two straight lines) in the longitudinal cross-sectional view of the storage tank 200. In addition, as illustrated in FIG. 10B, the collector 218 may be formed into a polygon having a pentagon or more in a transverse cross-sectional view of the storage tank 200. Note that the position of a straight line indicated by a dotted line in FIG. 10B is the position on the lowermost side (lower end) of the surface (inclined surface) of the collector 218. Also in the present modified example, effects can be obtained similar to those in the above-described embodiment.

### Modified Example 4

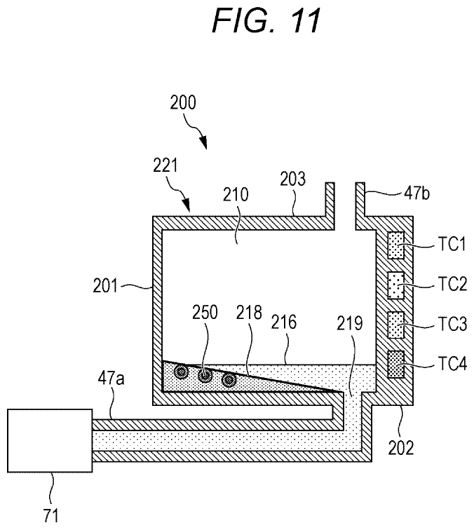

As illustrated in FIG. 11, the collector 218 may be configured to include at least one rod-shaped heater 250 therein. Also in the present modified example, effects can be obtained similar to those in the above-described embodiment. Furthermore, according to the configuration of the present modified example, the heater 250, which is, for example, a cartridge heater, can be provided at a portion closer to the liquid material 216 for heating, so that the vaporization efficiency of the liquid material 216 can be further improved.

### Modified Example 5

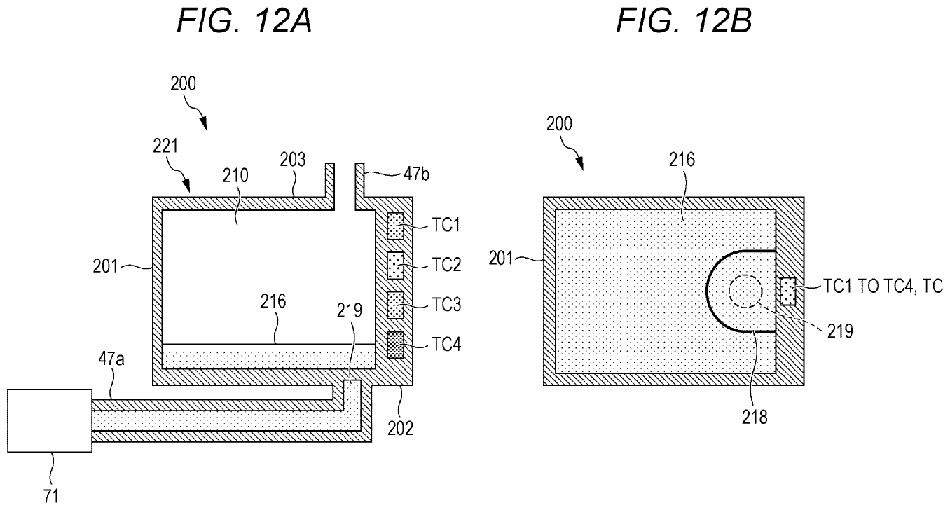

As illustrated in FIG. 12A, the collector 218 may be configured so as not to be visually recognized in a longitudinal cross-sectional view of the storage tank 200. Specifically, for example, as illustrated in FIG. 12B, the collector 218 may be formed in a mortar shape so as to be inclined toward the opening 219. Also in the present modified example, effects can be obtained similar to those in the above-described embodiment. Note that, also in a case where the collector 218 is provided at a central portion of the main body portion 221 in the transverse cross-sectional view illustrated in FIG. 12B, similarly, by disposing the temperature sensor TC4 near the opening 219, effects similar to those in the above-described embodiment can be obtained.

### OTHER EMBODIMENT OF PRESENT DISCLOSURE

The embodiments of the present disclosure have been specifically described above. Note that, the present disclosure is not limited to the embodiments described above, and can be variously modified without departing from the gist thereof.

For example, in the above embodiment, the case where the uppermost end of the collector 218 is arranged at a position higher than the arrangement position of the temperature sensor TC4 (see FIG. 4) and the case where the uppermost end of the collector 218 is arranged at a position lower than the lower end of the temperature sensor TC4 (see FIG. 8) have been described as examples. However, the present disclosure is not limited to such an embodiment. For example, the collector 218 may be disposed at a height facing the temperature sensor TC4. Here, arranging the collector 218 at a height facing the temperature sensor TC4 means, for example, arranging the temperature sensor TC4 between the uppermost end and the lowermost end of the collector 218. In the present embodiment also, effects similar to those in the embodiments described above can be obtained.

For example, in the above embodiment, in the longitudinal cross-sectional view of the storage tank 200, the case where the surface (inclined surface) of the collector 218 is configured to be indicated by one straight line (see FIG. 4) and the case where the surface is configured to be indicated by a plurality of straight lines (see FIGS. 10A and 10B) have been described as examples. However, the present disclosure is not limited to such an embodiment. For example, in the longitudinal cross-sectional view of the storage tank 200, the surface of the collector 218 may be configured by a combination of a straight line and a curved line, or may be configured by a curved line. In the present embodiment also, effects similar to those in the embodiments described above can be obtained.

For example, in the above-described embodiment, the four temperature sensors TC1 to TC4 have been described as an example of the plurality of temperature sensors. However, the present disclosure is not limited to such an embodiment. For example, two temperature sensors, three temperature sensors, or five or more temperature sensors may be used as the plurality of temperature sensors. In the present embodiment also, effects similar to those in the embodiments described above can be obtained.

For example, in the above-described embodiment, a plurality of temperature sensors is provided on the side wall 201 of the storage tank 200. However, the present disclosure is not limited to such an embodiment. For example, a component that protects the temperature sensor TC, such as a protective tube, needs to be added, but at least one or more temperature sensors among the four temperature sensors TC1 to TC4 can be arranged in the storage chamber 210. Even in this case, since the temperature sensor TC can be brought into contact with the liquid material 216, the remaining amount of the liquid material 216 can be estimated. In the present embodiment also, effects similar to those in the embodiments described above can be obtained.

Preferably, a recipe used in each processing is individually prepared according to processing contents and is recorded and stored in the memory 41c via a telecommunication line or the external memory 412. When each processing is started, the CPU 41a preferably appropriately selects an appropriate recipe from among a plurality of recipes recorded and stored in the memory 41c according to the processing contents. Thus, it is possible to form films with various film types, composition ratios, film qualities, and film thicknesses with excellent reproducibility with one processing apparatus. It is possible to reduce a burden on an operator, and to quickly start each processing while avoiding an operation error.

The recipe described above is not limited to a newly created recipe, but may be prepared by, for example, changing the existing recipe already installed in the processing apparatus. In a case of changing the recipe, the changed recipe may be installed in the processing apparatus via a telecommunication line or a recording medium in which the recipe is recorded. In addition, the existing recipe already installed in the processing apparatus may be directly changed by operating the input/output device 122 included in the existing processing apparatus.

Furthermore, in the present embodiment, the semiconductor manufacturing process has been described, but the present disclosure is not limited thereto. For example, the present disclosure can also be applied to substrate processing such as a liquid crystal device manufacturing process, a solar cell manufacturing process, a light emitting device manufacturing process, a glass substrate processing process, a ceramic substrate processing process, and a conductive substrate processing process.

In the above-described embodiment, an example has been described in which a film is formed using a batch-type processing apparatus that processes a plurality of substrates at a time. The present disclosure is not limited to the embodiment described above, and can be appropriately applied to a case of forming a film using a single wafer type processing apparatus that processes one or more substrates at a time, for example. In the above-described embodiments, an example has been described in which a film is formed by use of a processing apparatus including a hot wall type processing furnace. The present disclosure is not limited to the above-described embodiments, and is suitably applicable to a case where a film is formed by use of a processing apparatus including a cold wall type processing furnace.

Even in cases where such processing apparatuses are used, each piece of processing can be performed in accordance with processing procedures and processing conditions similar to those in the above-described embodiment and modified examples, so that effects can be obtained similar to those in the above-described embodiment and modified examples.

The embodiment and modified examples described above can be used in combination as appropriate. The processing procedures and processing conditions at that time can be similar to the processing procedures and processing conditions in the above-described embodiment and modified examples, for example.

According to the present disclosure, the remaining amount of a material can be estimated based on a temperature detected by a temperature sensor.

What is claimed is:

1. A vaporizer comprising:
a main body that stores a liquid material at room temperature;
a plurality of temperature sensors provided on a side wall of the main body; and
a collector formed to collect the material on a side wall side on which a temperature sensor disposed at a lower end among the plurality of temperature sensors is provided.

2. The vaporizer according to claim 1, wherein:
a supply port configured to supply the material is further provided in a bottom wall of the main body, and
the collector has a structure in which the material flows toward the supply port.

3. The vaporizer according to claim 2, wherein:
the supply port is provided at a position close to the temperature sensor disposed at the lower end among the plurality of temperature sensors.

4. The vaporizer according to claim 1, wherein:
an uppermost end of the collector is configured to be lower than the temperature sensor disposed at the lower end among the plurality of temperature sensors.

5. The vaporizer according to claim 1, wherein:
an uppermost end of the collector is configured to be disposed higher than the temperature sensor disposed at the lower end.

6. The vaporizer according to claim 5, wherein:
the collector is configured to be disposed at a height facing the temperature sensor disposed at the lower end among the plurality of temperature sensors.

7. The vaporizer according to claim 1, wherein:
a side wall of the main body is formed in an uneven shape, and
the plurality of temperature sensors is installed in the protrusion.

8. The vaporizer according to claim 1, wherein:
the plurality of temperature sensors is arranged so as to equally divide a side wall of the main body in a height direction in a longitudinal cross-sectional view.

9. The vaporizer according to claim 1, wherein:
a surface of the collector is configured to be indicated by at least one straight line in a longitudinal cross-sectional view.

10. The vaporizer according to claim 9, wherein:
a surface of the collector is configured to be indicated by a combination of a plurality of the straight lines or a combination of the straight line and a curve in a longitudinal cross-sectional view.

11. The vaporizer according to claim 1, wherein:
a surface of the collector is configured as indicated by a curve in a longitudinal cross-sectional view.

12. The vaporizer according to claim 1, further comprising:
a control portion configured to be able to determine a remaining amount of the material inside the main body according to a change in temperature measured by the plurality of temperature sensors.

13. The vaporizer according to claim 12, wherein:
the control portion is configured to determine that the remaining amount of the material is insufficient when a temperature of the temperature sensor disposed at the lower end among the plurality of temperature sensors changes.

14. The vaporizer according to claim 12, further comprising a liquid supplier, wherein:
the control portion is configured to cause the liquid supplier to replenish the material from the supply port.

15. The vaporizer according to claim 14, wherein:
the control portion is configured to cause the liquid supplier to stop supply of the material when a temperature of a temperature sensor disposed at an upper end of the plurality of temperature sensors is saturated.

16. The vaporizer according to claim 12, wherein:
the control portion is configured to supply the material from the supply port based on a temperature detected by the temperature sensor disposed at the lower end among the plurality of temperature sensors, the temperature sensor being provided near the supply port.

17. The vaporizer according to claim 1, wherein:
the main body is configured to provide at least one rod-shaped heater inside the collector.

18. A processing apparatus comprising a vaporizer, wherein the vaporizer includes:
a main body that stores a liquid material at room temperature;
a plurality of temperature sensors provided on a side wall of the main body; and
a collector formed to collect the material on a side wall side on which a temperature sensor disposed at a lower end among the plurality of temperature sensors is provided.

19. A processing method comprising:
arranging an object to be processed in a processing space; and
introducing a material gas generated by vaporizing a liquid material into the processing space via a vaporizer, the vaporizer including a main body that stores the liquid material at room temperature, a plurality of temperature sensors provided on a side wall of the main body, and a collector formed to collect the material on a side wall side on which a temperature sensor disposed at a lower end among the plurality of temperature sensors is provided.

20. A method of manufacturing a semiconductor device, the method comprising:
performing a predetermined process by supplying the material gas to a substrate containing a semiconductor using the processing method according to claim 19.
